(19) United States
(12) Patent Application Publication
(10) Pub. No.: US 2013/0112993 A1
(43) Pub. Date: May 9, 2013

(54) SEMICONDUCTOR DEVICE AND WIRING SUBSTRATE

(71) Applicant: Sumitomo Electric Industries, Ltd., Osaka-shi (JP)

(72) Inventors: Hideki HAYASHI, Osaka-shi (JP); Takashi TSUNO, Osaka-shi (JP)

(73) Assignee: Sumitomo Electric Industries, Ltd., Osaka-shi (JP)

(21) Appl. No.: 13/661,593

(22) Filed: Oct. 26, 2012

Related U.S. Application Data
(60) Provisional application No. 61/555,966, filed on Nov. 4, 2011.

(30) Foreign Application Priority Data
Nov. 4, 2011 (JP) 2011-241858

(51) Int. Cl. H01L 23/498; H01L 29/161; H01L 23/373; H01L 29/20

(52) U.S. Cl. 257/77; 257/76; 257/E23.072; 257/E29.089; 257/E29.084; 257/E23.109

(57) ABSTRACT

A semiconductor device according to one embodiment of the present invention includes an insulating substrate, a wiring layer formed on a first main surface of the insulating substrate and having a conductive property, and a semiconductor element mounted on the wiring layer. In the semiconductor device, the insulating substrate is composed of cBN or diamond.

### CROSS-REFERENCE RELATED APPLICATIONS

This application claims priority to Provisional Application serial No. 61/555,966 filed on Nov. 4, 2011 and claims the benefit of Japanese Patent Application No. 2011-241858, filed on Nov. 4, 2011, all of which are incorporated herein by reference in their entirety.

### BACKGROUND

1. Field

The embodiments of present invention relate to a semiconductor device and a wiring substrate.

2. Description of the Related Art

As an example of a semiconductor device, there is known a semiconductor device including a wiring substrate, and a semiconductor element mounted on the wiring substrate (see, Noriyuki Iwamuro, et al., “Manufacturing process of SiC/GaN Power Device and Heat dissipation/Cooling Technique”, the first edition, TECHNICAL INFORMATION INSTITUTE, CO., LTD., Feb. 26, 2010, p. 120). As the wiring substrate, a DBC (Direct Bonding Copper) substrate having a sandwich structure in which a ceramic substrate is sandwiched between a copper wiring and a heat dissipation layer made of copper is adopted. The semiconductor element is fixed by being soldered on the copper wiring of the wiring substrate. Further, the electrode on the upper portion of the semiconductor element (the side being opposite to the side of the insulating substrate) and the copper wiring are electrically connected to an aluminum wire, or the like. Terminals for external connection are soldered to the copper wiring, so that the semiconductor device is driven via the terminals.

### SUMMARY

However, when the semiconductor device is driven, heat is generated in the semiconductor device due to the driving. In this case, there is a case where the semiconductor device is damaged due to the difference in the thermal expansion coefficient, and the like, between the semiconductor element and the insulating substrate. In particular, a semiconductor device, in which a semiconductor element is composed of, for example, a wide bandgap semiconductor, can be used as a power module. In this case, the operation and stop of the semiconductor device are repeated, and hence the semiconductor device is subjected to a heat cycle. Under such a heat cycle, the semiconductor device tends to be easily damaged due to the difference in the thermal expansion coefficient. For this reason, it is required to improve the reliability of the semiconductor device.

To cope with this, an object of the present invention is to provide a semiconductor device and a wiring substrate which are able to realize high reliability.

A semiconductor device according to an aspect of the present invention includes an insulating substrate, a wiring layer formed on a first main surface of the insulating substrate and having a conductive property, and a semiconductor element composed of a wide bandgap semiconductor and mounted on the wiring layer. The insulating substrate is composed of cBN or diamond.

In this configuration, since the insulating substrate composed of cBN or diamond is used, the heat dissipation characteristic is improved, and the difference in the thermal expansion coefficient between the semiconductor element and the insulating substrate is reduced. As a result, the reliability of the semiconductor device is improved.

In one embodiment, the wiring layer is composed of a copper-containing material which contains copper and a specific metal having a thermal expansion coefficient smaller than the thermal expansion coefficient of copper, and the thermal expansion coefficient of the copper-containing material contained in the wiring layer can be made smaller than the thermal expansion coefficient of copper. In such configuration, it is possible to reduce the difference in the thermal expansion coefficient between the semiconductor element and the wiring layer, and between the wiring layer and the insulating substrate, respectively. As a result, it is possible to further improve the reliability of the semiconductor device.

In one embodiment, the copper-containing material constituting the wiring layer can be a composite material having a laminated structure in which a first layer composed of copper, and a second layer composed of the specific metal are laminated together.

Further, the copper-containing material constituting the wiring layer can be an alloy containing copper and the specific metal. In the case where the copper-containing material constituting the wiring layer is the composite material, the copper-containing material constituting the wiring layer can be easily manufactured. Further, in the case where the copper-containing material constituting the wiring layer is the alloy, the thermal expansion coefficient of the copper-containing material constituting the wiring layer is more easily adjusted.

In the case where the copper-containing material constituting the wiring layer is the composite material, the composite material can be configured by laminating a first layer, a second layer, and a third layer in this order. In this case, the second layer is sandwiched by the first layers composed of copper, and the surface of the wiring layer is composed of copper. As a result, similarly to the case where the wiring layer is composed of copper, the wiring layer can be joined to the insulating substrate.

In one embodiment, the specific metal can be molybdenum or tungsten. The thermal expansion coefficient of molybdenum and tungsten is equal to or smaller than a half of the thermal expansion coefficient of copper. For this reason, in the case where the specific metal is molybdenum or tungsten, the copper-containing material having a thermal expansion coefficient smaller than the thermal expansion coefficient of copper can be easily formed.

In one embodiment, the wide bandgap semiconductor can be SiC or GaN. Especially, among wide bandgap semiconductors, SiC or GaN has been used for a power module. Therefore, there is a tendency that a semiconductor device in the form in which the wide bandgap semiconductor is SiC or GaN is used as a power module. A heat cycle is generated in the power module, and hence a smaller difference in the thermal expansion coefficient between the semiconductor element and the wiring substrate is preferred. Therefore, the form, in which the wide bandgap semiconductor is SiC or GaN, is especially effective as a semiconductor device for use in the power module.

In one embodiment, the semiconductor device can include a heat dissipation layer formed on a second main surface on the opposite side of the first main surface of the insulating substrate, and a heat sink joined to the insulating substrate via the heat dissipation layer. In this form, the heat dissipation layer can be composed of a copper-containing material containing copper. Also, the thermal expansion coefficient of the copper-containing material contained in the heat dissipation layer can be larger than the thermal expansion coefficient of the insulating substrate and equal to or smaller than the thermal expansion coefficient of the heat sink.

In this case, the insulating substrate and the heat sink are joined to each other via the heat dissipation layer composed of the copper-containing material containing copper, and the difference in the thermal expansion coefficient between the insulating substrate and the heat sink can be reduced. As a result, the thermal stress, and the like, between the insulating substrate and the heat sink are reduced. Therefore, the reliability of the semiconductor device is further improved.

The semiconductor device, in which the wiring layer is composed of the copper-containing material containing copper and a specific metal having a thermal expansion coefficient smaller than the thermal expansion coefficient of copper, may include a heat dissipation layer formed on the second main surface on the opposite side of the first main surface of the insulating substrate. Further, the heat dissipation layer can be composed of the copper-containing material. In this case, the same material is provided on the first main surface and the second main surface of the insulating substrate, and hence the insulating substrate is hardly warped.

Another aspect of the present invention relates to a wiring substrate on which a semiconductor element is mounted. The wiring substrate includes an insulating substrate, and a wiring layer which is formed on a main surface of the insulating substrate and on which the semiconductor element is mounted. The insulating substrate is formed of cBN or diamond.

In this configuration, since the insulating substrate composed of cBN or diamond is used, the heat dissipation characteristic is improved, and the difference in the thermal expansion coefficient between the semiconductor element and the insulating substrate is reduced. Therefore, even when the semiconductor element is driven to generate heat, the thermal distortion or thermal stress, which is generated between the semiconductor element and the insulating substrate, is reduced. As a result, the semiconductor element mounted on the wiring substrate can be stably driven, and hence the reliability of the device including the wiring substrate and the semiconductor element is improved.

As mentioned above, a semiconductor device which can realize high reliability and a wiring substrate on which a semiconductor element is mounted can be provided.

### BRIEF DESCRIPTION OF THE DRAWINGS

FIG. 1 is a cross-sectional view showing a schematic configuration of a semiconductor device according to one embodiment;

FIG. 2 is a perspective view showing an example of a wiring substrate provided in the semiconductor device shown in FIG. 1; and

FIG. 3 is a schematic view showing an example of a configuration of wiring layers provided in the wiring substrate shown in FIG. 2.

### DETAILED DESCRIPTION

In the following, embodiments according to the present invention will be described with reference to the accompanying drawings. In the description with reference to the accompanying drawings, the same components are denoted by the same reference numerals and characters, and the description thereof is omitted. The size and proportion of the accompanying drawings do not necessarily match those described. In the description, the terms, such as “upper” and “lower” indicating the directions are terms which are used for the sake of convenience based on the state shown in the accompanying drawings.

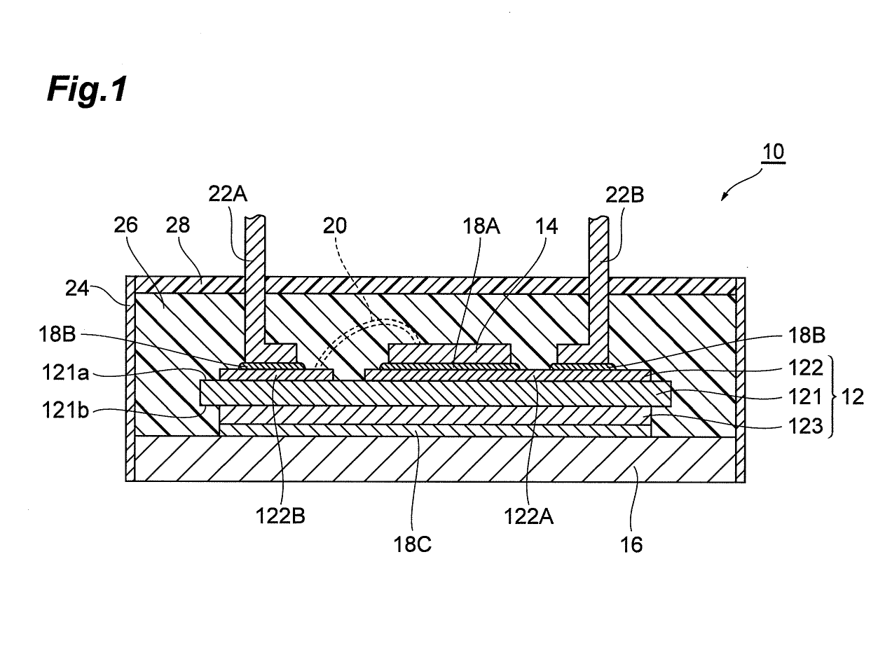

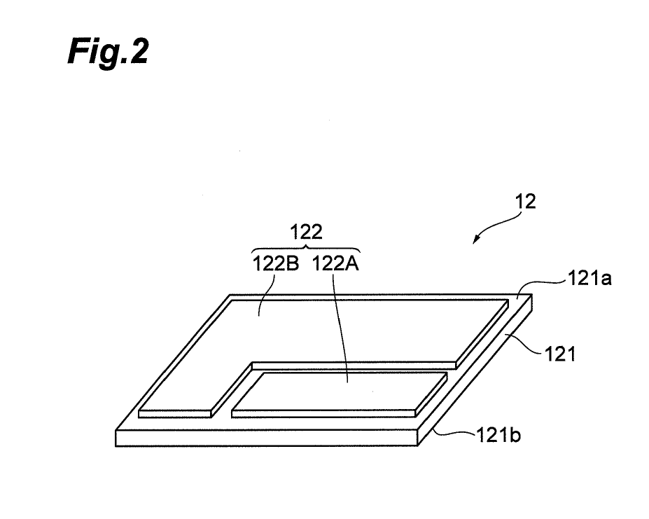

FIG. 1 is a cross-sectional view showing a schematic configuration of a semiconductor device according to one embodiment. FIG. 2 is a perspective view of a wiring substrate provided in the semiconductor device shown in FIG. 1. A semiconductor device 10 is a semiconductor module including a wiring substrate 12 and a semiconductor element 14 mounted on the wiring substrate 12. The semiconductor device 10 can be a power module used, for example, in a power source, and the like. It is preferred that the semiconductor device 10 includes a heat sink 16 arranged on the opposite side of the semiconductor element 14 respect to the wiring substrate 12. In the following, unless otherwise specified, the semiconductor device 10 is described by using, as an example, the form of the semiconductor device 10 provided with the heat sink 16.

Examples of the semiconductor element 14 include an insulation type field effect transistor (MOSFET), a junction type field effect transistor, and a bipolar transistor. Examples of MOSFET include a vertical type MOSFET and a lateral type MOSFET. The semiconductor which forms the semiconductor element 14 is a so-called wide bandgap semiconductor. Examples of the wide gap semiconductor include SiC and GaN.

As shown in FIG. 1 and FIG. 2, the wiring substrate 12 has an insulating substrate 121, and a conductive wiring layer 122 provided on a surface (first main surface) 121 a of the insulating substrate 121.

Examples of the shape of the insulating substrate 121 in plan view can include a rectangle and a square. The thickness of the insulating substrate 121 is, for example, in the range of 100 μm to 1000 μm. The insulating substrate 121 is composed of cBN (cubic boron nitride) or diamond. The material of cBN or diamond may be a single crystal, a poly-crystal, or a sintered compact. Note that it is only necessary that the insulating substrate 121 is substantially composed of cBN or diamond. For example, it is only necessary that the main material of the insulating substrate 121 is cBN or diamond.

The wiring layer 122 can be joined to the insulating substrate 121 via a brazing material, or the like or directly. The thickness of the wiring layer 122 is, for example, in the range of 100 μm to 500 μm. With such thickness, it is possible that the influence of difference in the thermal expansion coefficient is reduced, and that large current is made to flow. The wiring layer 122 includes a plurality of conductive wiring regions (hereinafter referred to simply as wirings) 122A and 122B insulated from each other. Each of the plurality of wirings 122A and 122B is arranged in a predetermined wiring pattern. In FIG. 1, the two wirings 122A and 122B are shown as examples, but the number of wirings is not limited to two.

The semiconductor element 14 is mounted on the wiring 122A which forms a part of the wiring layer 122. The semiconductor element 14 is soldered to the wiring 122A. That is, a layered solder 18A as an adhesive layer is provided between the semiconductor element 14 and the wiring layer 122. An example of the solder 18A is a Sn—Ag—Cu based solder. In the case where the semiconductor element 14 is a vertical type MOSFET, the lower portion of the semiconductor element 14 is a drain electrode. Therefore, the wiring 122A and the semiconductor element 14 are electrically connected to each other by fixing the semiconductor element 14 to the wiring 122A by using the solder 18A. The electrode provided at the upper portion of the semiconductor element 14 is electrically connected to the wiring 122B via a wire 20, such as an aluminum wire. In the case where the semiconductor element 14 has no electrode at the lower portion thereof, the semiconductor element 14 and the wiring 122A can be electrically connected to each other in such a manner that an electrode, which is provided at the upper portion of the semiconductor element 14 separately from the electrode to be connected to the wiring 122B, is wire-bonded to the wiring 122A.

Terminals 22A and 22B are respectively fixed to the wirings 122A and 122B by a solder 18B, and the like, and thereby the semiconductor element 14 can be externally connected by using the terminals 22A and 22B. An example of the solder 18B is a Sn—Ag—Cu based solder. Here, an example of the connection relation between the semiconductor element 14 and the wiring layer 122 is shown. However, it is only necessary that the semiconductor element 14 and the wiring layer 122 are electrically connected to each other so that the semiconductor element 14 is operated by using the terminals 22A and 22B, and the like, which are connected to the wiring layer 122.

It is preferred that the wiring layer 122 is composed of a first copper-containing material which contains copper and which has a thermal expansion coefficient smaller than the thermal expansion coefficient of copper. In one embodiment, the thermal expansion coefficient of the first copper-containing material can be set to a value which is smaller than the thermal expansion coefficient of copper, and is equivalent to or larger than the thermal expansion coefficient of the semiconductor constituting the semiconductor element 14. The first copper-containing material contains copper (thermal expansion coefficient: about 16.8×10⁻⁶/K), and the other specific metal having a thermal expansion coefficient smaller than the thermal expansion coefficient of copper. Preferably, such a first copper-containing material can be a composite material or an alloy. Examples of the specific metal include molybdenum (thermal expansion coefficient: about 5.1×10⁻⁶/K) and tungsten (thermal expansion coefficient: about 4.5×10⁻⁶/K). It is only necessary that the first copper-containing material contains one kind of the other specific material different from copper, as long as the first copper-containing material has a thermal expansion coefficient smaller than the thermal expansion coefficient of copper. Therefore, the first copper-containing material may contain two or more kinds of metals different from copper.

In the case where the first copper-containing material is a composite material containing copper and the other specific metal having a thermal expansion coefficient smaller than the thermal expansion coefficient of copper, it is preferred that the composite material can have a laminated structure in which a layer (first layer) made of copper and a layer (second layer) made of the specific metal are laminated together.

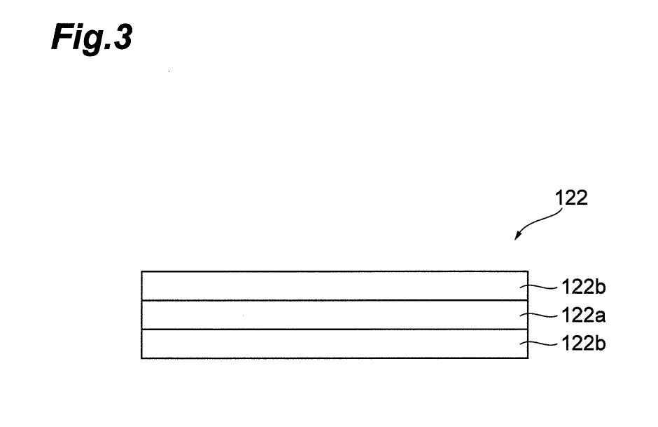

FIG. 3 is a schematic view showing an example of the wiring layer in the case where the first copper-containing material is a composite material. In the form shown in FIG. 3, the wiring layer 122 is composed of a composite material of a three-layer structure which includes an intermediate layer (second layer) 122a made of a specific metal having a thermal expansion coefficient smaller than the thermal expansion coefficient of copper, and surface layers (first layers) 122b and 122b made of copper, and which is formed by laminating the surface layer 122b, the intermediate layer 122a, and the surface layer 122b in this order. In the form shown in FIG. 3, the surface facing the insulating substrate 121 is composed of copper. In this case, the wiring layer 122 can be directly joined to the insulating substrate 121 similarly to, for example, the case of the DBC (Direct Bonding Copper) substrate. The layer structure of the composite material may be a two-layer structure or a structure having four or more layers. In the case where the composite material has three or more layers, the materials constituting the respective layers may be different from each other.

An example of the composite material as the first copper-containing material constituting the wiring layer 122 is a Cu—Mo—Cu composite material in which the intermediate layer 122a shown in FIG. 3 is composed of molybdenum (Mo).

Further, an example of the first copper-containing material as an alloy made of copper and the other specific metal is a Cu—W alloy in which the other specific metal is tungsten (W), or a Cu—Mo alloy in which the other specific metal is molybdenum.

Preferably, the wiring substrate 12 may include a heat dissipation layer 123 provided on the back surface (second main surface) 121b on the opposite side of the surface 121 a of the insulating substrate 121. The heat dissipation layer 123 can be formed so as to cover the whole back surface 121b. The heat dissipation layer 123 can be joined to the back surface 121b via a brazing material, or the like or directly, similarly to the case of the wiring layer 122. When the heat dissipation layer 123 is possessed in this manner, it is preferred that the heat dissipation layer 123 can be composed of a second copper-containing material containing copper. The thermal expansion coefficient of the second copper-containing material constituting the heat dissipation layer 123 is larger than the thermal expansion coefficient of the insulating substrate 121, and is equal to or smaller than the thermal expansion coefficient of the heat sink 16.

As will be described below, as an example, in the case where the heat sink 16 is composed of copper, the second copper-containing material constituting the heat dissipation layer 123 can be copper. However, the composition of the second copper-containing material constituting the heat dissipation layer 123 may be the same as the composition of the first copper-containing material constituting the wiring layer 122. In this case, the second copper-containing material constituting the heat dissipation layer 123 may be the composite material or the alloy which is shown as the first copper-containing material constituting the wiring layer 122 as an example. In the case where the first copper-containing material is the same as the second copper-containing material, a difference hardly occurs in the thermal expansion coefficient between the side of the surface 121 a of the insulating substrate 121 and the side of the back surface 121b of the insulating substrate 121, and hence the wiring substrate 12 is hardly warped.

The heat sink 16 is a metal plate. It is only necessary that the heat sink 16 is composed of a metal having high thermal conductivity. An example of the metal constituting the heat sink 16 is copper. Examples of the shape of the heat sink 16 in plan view include a rectangle and a square. In one embodiment, the heat sink 16 can be joined to the opposite side of the surface of the wiring substrate 12 via a solder 18C. An example of the solder 18C is a Sn—Ag—Cu based solder. In the case where the heat dissipation layer 123 is formed on the back surface of the wiring substrate 12, as shown in FIG. 1, between the insulating substrate 121 and the heat sink 16, the heat dissipation layer 123 and the layered solder 18C are sandwiched in this order from the side of the insulating substrate 121.

As shown in FIG. 1, the semiconductor device 10 can have a frame-like resin case 24 surrounding the heat sink 16. Examples of the material of the resin case 24 include engineering plastics, such as polybutylene terephthalate (PBT), and polyphenylene sulfide resin (PPS). The resin case 24 is fixed to the outer edge portion of the heat sink 16. For example, into the inside of the resin case 24, a silicone gel 26 can be injected for stress relaxation. Further, as shown in FIG. 1, the wiring substrate 12, the semiconductor element 14, and the like, which are embedded in the silicone gel 26, can be hermetically sealed by thermoplastic resin 28, such as epoxy resin. Note that the wiring substrate 12, the semiconductor element 14, and the like, may be directly embedded by the thermoplastic resin 28 without via the silicone gel 26.

In the semiconductor device 10 configured as described above, the insulating substrate 121 is composed of cBN or diamond which has higher thermal conductivity and a smaller thermal expansion coefficient as compared with the material constituting the conventional insulating substrate. Therefore, in the semiconductor device 10, the heat dissipation characteristic is improved, and the difference in the thermal expansion coefficient between the semiconductor element 14 and the insulating substrate 121 is reduced.

This point will be specifically described by use of specific numeral values. The thermal expansion coefficients of SiC and GaN, each of which is an example of a wide bandgap semiconductor constituting the semiconductor element 14, are about 4.2×10⁻⁶/K and about 5.6×10⁻⁶/K, respectively. On the other hand, AlN (aluminum nitride), which is a typical material constituting the conventional insulating substrate, has a thermal expansion coefficient of about 4.5×1⁻⁶/K, and thermal conductivity of about 150 W/m·K. On the other hand, cBN has a thermal expansion coefficient of about 4.7×10⁻⁶/K, and thermal conductivity of about 1300 W/m·K. Diamond has a thermal expansion coefficient of about 2.3×10⁻⁶/K, and thermal conductivity of about 2000 W/m·K. In this way, cBN or diamond, which is used to form the insulating substrate 121, has higher thermal conductivity and a smaller thermal expansion coefficient as compared with the material, for example, AlN, which is used to form the conventional insulating substrate. Thereby, in the semiconductor device 10, the heat dissipation characteristic is improved, and the difference in the thermal expansion coefficient between semiconductor element 14 and the insulating substrate 121 is reduced. In this case, the thermal expansion itself is hardly caused, and even when the thermal expansion is caused, the influence of the thermal expansion is reduced. Therefore, the thermal distortion or the thermal stress caused between the semiconductor element 14 and the insulating substrate 121 is reduced. Thereby, damage of the semiconductor element 14 or damage of the joint portion between the semiconductor element 14 and the insulating substrate 121 is suppressed, and hence the reliability of the semiconductor device 10 is improved.

Further, in the case where the insulating substrate 121 is composed of diamond, the heat dissipation characteristic is further improved. Further, in the case where the insulating substrate 121 is composed of cBN, the manufacturing cost of the semiconductor device 10 can be reduced, and at the same time, the reliability of the semiconductor device 10 can be improved.

The semiconductor device 10 provided with the semiconductor element 14 including a wide bandgap semiconductor can be used as a so-called power module as described above. In the semiconductor device 10 used as a power module, each of SiC and GaN shown above as an example is used, in particular, as the wide bandgap semiconductor. The operation and stop of the power module are repeated, and hence the semiconductor device 10 is subjected to a heat cycle. Even in the case where the semiconductor device is subjected to the heat cycle, when the insulating substrate 121 having a thermal expansion coefficient closer to the thermal expansion coefficient of the semiconductor element 14 is adopted, damage of the semiconductor element 14, and the like, is hardly caused by thermal distortion due to thermal expansion, or by thermal stress. Further, when the insulating substrate 121 having a higher heat dissipation characteristic is adopted, thermal expansion itself can be suppressed. For this reason, the configuration of the semiconductor device 10, especially the configuration, in which SiC or GaN is adopted as a wide bandgap semiconductor, is very effective in the case where the semiconductor device 10 is used as a power module.

Further, in the form in which the wiring layer 122 is composed of the first copper-containing material containing copper and the other specific metal having a thermal expansion coefficient smaller than the thermal expansion coefficient of copper, the thermal expansion coefficient of the wiring layer 122 becomes smaller than the thermal expansion coefficient of the wiring layer composed only of copper, and becomes closer to the thermal expansion coefficient of the semiconductor element 14 and the insulating substrate 121. Thereby, it is possible to reduce the difference in the thermal expansion coefficient between the semiconductor element 14 and the wiring layer 122, and between the wiring layer 122 and the insulating substrate 121, respectively. In the case where the differences in the thermal expansion coefficient are reduced in this way, even when the semiconductor device 10 is driven to generate heat, the stress acting on the joint portion between the semiconductor element 14 and the wiring layer 122, and between the wiring layer 122 and the insulating substrate 121, respectively, are further reduced, and hence a crack, and the like, is hardly caused in each of the joint portions described above. Therefore, the reliability of the semiconductor device 10 is further improved. In other words, the semiconductor device 10 having higher reliability can be realized by using the wiring substrate 12 provided with the wiring layer 122.

Further, the thermal conductivity of copper contained in the first copper-containing material is higher than, for example, the thermal conductivity of tungsten or molybdenum. Therefore, in the case where the wiring layer 122 is composed of the first copper-containing material, the heat dissipation characteristic of the wiring layer 122 is better than, for example, the case where the wiring layer is composed only of tungsten or molybdenum. For this reason, in the form in which the wiring layer 122 is composed of the first copper-containing material, the stress due to the difference in the thermal expansion coefficient between the wiring layer 122 and the semiconductor element 14, and between the wiring layer 122 and the insulating substrate 121, respectively, is further easily reduced.

In the case where the wiring layer 122 is composed of the composite material having the laminated structure as shown in FIG. 3, the first copper-containing material is easily manufactured. As shown in FIG. 3, in the case where the surface layer 122b of the three-layer structure is composed of copper, the wiring layer 122 can be fixed to the insulating substrate 121 similarly to the case of the DBC substrate.

As described above, the first copper-containing material constituting the wiring layer 122 can be an alloy (for example, a Cu—W alloy or a Cu—Mo alloy) made of copper, and the specific metal having a thermal expansion coefficient smaller than the thermal expansion coefficient of copper. In the case of such an alloy, the thermal expansion coefficient of the alloy can be adjusted by adjusting the content percentage of the specific metal. For this reason, the thermal expansion coefficient of the first copper-containing material can be easily adjusted.

Further, the thermal expansion coefficient of molybdenum and tungsten is equal to or smaller than a half of the thermal expansion coefficient of copper. Therefore, in the case where the specific metal is molybdenum or tungsten, the copper-containing material having a thermal expansion coefficient smaller than the thermal expansion coefficient of copper can be easily formed.

Further, in the form in which the wiring substrate 12 is provided with the heat dissipation layer 123, and in which the heat dissipation layer 123 is composed of a second copper-containing material having a thermal expansion coefficient which is larger than the thermal expansion coefficient of the insulating substrate 121, and is equal to or smaller than the thermal expansion coefficient of the heat sink 16, the difference in the thermal expansion coefficient between the heat dissipation layer 123 and the heat sink 16 is also reduced. As a result, even when the semiconductor device 10 is driven to generate heat, damage, such as a crack, is hardly caused in the joint portion (the portion of the layered solder 18C in FIG. 1) between the heat dissipation layer 123 and the heat sink 16. Therefore, the reliability of the semiconductor device 10 is further improved. Further, similarly to the case of the wiring layer 122, in the case where the heat dissipation layer 123 is composed of a material containing copper as in the second copper-containing material, the heat dissipation characteristic of the heat dissipation layer 123 is improved more than the case where the heat dissipation layer is composed only of tungsten or molybdenum. Thereby, the stress due to the difference in the thermal expansion coefficient is further reduced.

In the form in which the wiring substrate 12 is provided with the heat dissipation layer 123, it is preferred that the second copper-containing material constituting the heat dissipation layer 123 is the first copper-containing material constituting the wiring layer 122. In this case, a difference in the thermal expansion coefficient between the surface 121a and the back surface 121b of the insulating substrate 121 is hardly caused, and hence the wiring substrate 12 is hardly warped.

In the above, the embodiments according to the present invention are described, but the present invention is not limited to the above described embodiments, and various modifications are possible within the scope and spirit of the present invention. For example, in the semiconductor device used as a semiconductor module, a unit formed of the wiring substrate 12 and the semiconductor element 14 may be a semiconductor device. Although the first and second copper-containing materials containing copper are shown as materials respectively constituting the wiring layer 122 and the heat dissipation layer 123 as an example, but each of the wiring layer 122 and the heat dissipation layer 123 may be composed only of copper. Further, as described above, it is only necessary that the insulating substrate 121 is substantially composed of cBN or diamond, and hence the insulating substrate 121 may contain, for example, the other material within the scope and spirit of the present invention.

What is claimed is:

1. A semiconductor device comprising:
an insulating substrate;
a wiring layer formed on a first main surface of the insulating substrate and having a conductive property; and
a semiconductor element composed of a wide bandgap semiconductor and mounted on the wiring layer,
wherein the insulating substrate is composed of cBN or diamond.

2. The semiconductor device according to claim 1, wherein
the wiring layer is composed of a copper-containing material containing copper and a specific metal having a thermal expansion coefficient smaller than the thermal expansion coefficient of copper, and
the thermal expansion coefficient of the copper-containing material contained in the wiring layer is smaller than the thermal expansion coefficient of copper.

3. The semiconductor device according to claim 2, wherein
the copper-containing material constituting the wiring layer is a composite material having a laminated structure in which a first layer composed of copper, and a second layer composed of the specific metal are laminated together, or
the copper-containing material constituting the wiring layer is an alloy containing copper and the specific metal.

4. The semiconductor device according to claim 3, wherein the composite material is configured by laminating the first layer, the second layer, and the first layer in this order.

5. The semiconductor device according to claim 2, wherein the specific metal is molybdenum or tungsten.

6. The semiconductor device according to claim 1, wherein the wide bandgap semiconductor is SiC or GaN.

7. The semiconductor device according to claim 1, comprising:
a heat dissipation layer formed on a second main surface on the opposite side of the first main surface of the insulating substrate; and
a heat sink joined to the insulating substrate via the heat dissipation layer,
wherein the heat dissipation layer is composed of a copper-containing material containing copper, and
the thermal expansion coefficient of the copper-containing material contained in the heat dissipation layer is larger than the thermal expansion coefficient of the insulating substrate and is equal to or smaller than the thermal expansion coefficient of the heat sink.

8. The semiconductor device according to claim 2, comprising:
a heat dissipation layer formed on a second main surface on the opposite side of the first main surface of the insulating substrate,
wherein the heat dissipation layer is composed of the copper-containing material.

9. A wiring substrate on which a semiconductor element is mounted, comprising:
an insulating substrate; and
a wiring layer which is formed on a main surface of the insulating substrate and on which the semiconductor element is mounted,
wherein the insulating substrate is composed of cBN or diamond.
